(19) United States
(12) Patent Application Publication
(10) Pub. No.: US 2015/0311325 A1
(43) Pub. Date: Oct. 29, 2015

(54) IGBT STRUCTURE ON SIC FOR HIGH PERFORMANCE

(71) Applicant: CREE, INC., DURHAM, NC (US)

(72) Inventor: Qingchun Zhang, Cary, NC (US)

(73) Assignee: CREE, INC., DURHAM, NC (US)

(21) Appl. No.: 14/259,821

(22) Filed: Apr. 23, 2014

(51) Int. Cl. H01L 29/739; H01L 29/10; H01L 21/265; H01L 29/08; H01L 29/66; H01L 29/16; H01L 29/06

(52) U.S. Cl. CPC H01L 29/7395; H01L 29/1608; H01L 29/1095; H01L 29/0615; H01L 29/0821; H01L 29/0804; H01L 29/1004; H01L 29/66333; H01L 21/265

(57) ABSTRACT

An IGBT device includes an IGBT stack including a first surface and a second surface opposite the first surface, a collector contact over the first surface of the IGBT stack, a gate contact on the second surface of the IGBT stack, and an emitter contact on the second surface of the IGBT stack. The IGBT stack includes an injector region, which provides the first surface of the IGBT stack, a drift region over the injector region opposite the first surface, a pair of junction implants in the IGBT stack along the second surface of the IGBT stack, and a field termination region between the pair of junction implants in the IGBT stack along the second surface of the IGBT stack.

### FIELD OF THE DISCLOSURE

The present disclosure relates to insulated gate bipolar transistor (IGBT) devices and structures and methods of manufacturing the same.

### BACKGROUND

The insulated gate bipolar transistor (IGBT) is a semiconductor device that combines many of the desirable properties of a field-effect transistor (FET) with those of a bipolar junction transistor (BJT). An exemplary conventional IGBT device 10 is shown in FIG. 1. The conventional IGBT device 10 shown in FIG. 1 represents a single IGBT cell that includes an IGBT stack 12, a collector contact 14, a gate contact 16, and an emitter contact 18. The IGBT stack 12 includes an injector region 20 adjacent to the collector contact 14, a drift region 22 over the injector region 20 and adjacent to the gate contact 16 and the emitter contact 18, and a pair of junction implants 24 in the drift region 22. The injector region 20 provides a first surface 26 of the IGBT stack 12 on which the collector contact 14 located. Further, the drift region 22 provides a second surface 28 of the IGBT stack 12 opposite the first surface 26 on which the gate contact 16 and the emitter contact 18 are located.

Each one of the junction implants 24 is generally formed by an ion implantation process, and includes a base well 30, a source well 32, and an ohmic well 34. Each base well 30 is implanted in the IGBT stack 12 along the second surface 28 of the IGBT stack 12, and extends down towards the injector region 20 along a lateral edge 36 of the IGBT stack 12. The source well 32 and the ohmic well 34 are formed in a shallow portion of the IGBT stack 12 along the second surface 28 of the IGBT stack 12, and are surrounded by the base well 30. A JFET gap 38 separates each one of the junction implants 24, and defines a JFET gap width W_{JFET} as the distance between each one of the junction implants 24 in the conventional IGBT device 10.

A gate oxide layer 40 is positioned on the second surface 28 of the IGBT stack 12, and extends laterally between a portion of the surface of each one of the source wells 32, such that the gate oxide layer 40 partially overlaps and runs between the surface of each source well 32 in the junction implants 24. The gate contact 16 is positioned over the gate oxide layer 40. The emitter contact 18 includes two portions in contact with the second surface 28 of the IGBT stack 12. Each portion of the emitter contact 18 on the second surface 28 of the IGBT stack 12 partially overlaps both the source well 32 and the ohmic well 34 of one of the junction implants 24, respectively, without contacting the gate contact 16 or the gate oxide layer 40.

A first junction J₁ between the injector region 20 and the drift region 22, a second junction J₂ between each base well 30 and the drift region 22, and a third junction J₃ between each source well 32 and each base well 30 are controlled to operate in one of a forward-bias mode of operation or a reverse-bias mode of operation based on the biasing of the conventional IGBT device 10. Accordingly, the flow of current between the collector contact 14 and the emitter contact 18 is controlled.

The conventional IGBT device 10 has three primary modes of operation. When a positive bias is applied to the gate contact 16 and the emitter contact 18, and a negative bias is applied to the collector contact 14, the conventional IGBT device 10 operates in a reverse blocking mode. In the reverse blocking mode of the conventional IGBT device 10, the first junction J₁ and the third junction J₃ are reverse-biased, while the second junction J₂ is forward biased. As will be understood by those of ordinary skill in the art, the reverse-biased junctions J₁ and J₃ prevent current from flowing from the collector contact 14 to the emitter contact 18. Accordingly, the drift region 22 supports the majority of the voltage across the collector contact 14 and the emitter contact 18.

When a negative bias is applied to the gate contact 16 and the emitter contact 18, and a positive bias is applied to the collector contact 14, the conventional IGBT device 10 operates in a forward blocking mode. In the forward blocking mode of the conventional IGBT device 10, the first junction J₁ and the third junction J₃ are forward biased, while the second junction J₂ is reverse-biased. As will be understood by those of ordinary skill in the art, the reverse-bias of the second junction J₂ generates a depletion region, which effectively pinches off the JFET gap 38 of the IGBT device 10 and prevents current from flowing from the collector contact 14 to the emitter contact 18. Accordingly, the drift region 22 supports the majority of the voltage across the collector contact 14 and the emitter contact 18.

When a positive bias is applied to the gate contact 16 and the collector contact 14, and a negative bias is applied to the emitter contact 18, the conventional IGBT device 10 operates in a forward conduction mode of operation. In the forward conduction mode of operation of the conventional IGBT device 10, the first junction J₁ and the third junction J₃ are forward-biased, while the second junction J₂ is reverse-biased. The positive bias applied to the gate contact 16 generates an inversion channel on the second surface 28 of the IGBT stack 12, thereby creating a low-resistance path for electrons to flow from the emitter contact 18 through each one of the source wells 32 and each one of the base wells 30 into the drift region 22. As electrons flow into the drift region 22, the potential of the drift region 22 is decreased, thereby placing the first junction J₁ in a forward-bias mode of operation. When the first junction J₁ becomes forward-biased, holes are allowed to flow from the injector region 20 into the drift region 22. The holes effectively increase the doping concentration of the drift region 22, thereby increasing the conductivity thereof. Accordingly, electrons from the emitter contact 18 may flow more easily through the drift region 22 and to the collector contact 14.

The IGBT stack 12 of the conventional IGBT device 10 is Silicon (Si), the advantages and shortcomings of which are well known to those of ordinary skill in the art. In an attempt to further increase the performance of IGBT devices, many have focused their efforts on using wide band-gap materials such as Silicon Carbide (SiC) for the IGBT stack 12. Although promising, conventional IGBT structures such as the one shown in FIG. 1 are generally unsuitable for use with wide band-gap materials such as SiC. Due to inherent limitations in SiC fabrication processes, the carrier mobility and/or carrier concentration in the injector region 20 in a SiC IGBT device may be significantly diminished. Specifically, the conductivity in the injector region 20 will be low in a SiC device due to difficulties in growing high quality P-type epitaxial layers with low defect density. Further, due to damage in the drift region 22 caused by the ion implantation of the junction implants 24, the lifetime of carriers in the area directly below each junction implant 24 is significantly diminished. The result of the aforementioned conditions in a SiC IGBT device is that holes from the injector region 20 do not adequately modulate the conductivity of the portion of the drift region 22 above a certain distance from the injector region 20. Accordingly, electrons from the emitter contact 18 are met with a high-resistance path in the upper portion of the drift region 22, thereby increasing the on resistance R_{ON} of the conventional IGBT device 10 significantly, or cutting off current flow in the device altogether.

In addition to the shortcomings discussed above, the conventional IGBT device 10 may also suffer from a large ON-state resistance due to one or more constraints placed on the JFET gap width W_{JFET}. Specifically, the JFET gap width W_{JFET} of the conventional IGBT device 10 may be constrained due to the presence of a large electric field between each one of the junction implants 24 during a voltage blocking operation, which may cause damage to the IGBT stack and/or the gate oxide layer 40. As will be understood by those of ordinary skill in the art, the electric field presented between the junction implants 24 is proportional to the JFET gap width W_{JFET}. Further, the JFET gap width W_{JFET} is directly related to the ON-state resistance of the conventional IGBT device 10, while the electric field presented between the junction implants 24 is directly related to the longevity of the conventional IGBT device 10. Designers of the conventional IGBT device 10 must thus balance the JFET gap width W_{JFET} and ON-state resistance of the conventional IGBT device 10 against the peak electric field presented between each one of the junction implants 24 and longevity of the conventional IGBT device 10, generally resulting in sub-optimal performance of the conventional IGBT device 10. Accordingly, an improved IGBT structure is needed that is suitable for use with wide band-gap semiconductor materials such as SiC.

### SUMMARY

The present disclosure relates to insulated gate bipolar transistor (IGBT) devices and structures. According to one embodiment, an IGBT device includes an IGBT stack including a first surface and a second surface opposite the first surface, a collector contact over the first surface of the IGBT stack, a gate contact on the second surface of the IGBT stack, and an emitter contact on the second surface of the IGBT stack. The IGBT stack includes an injector region, which provides the first surface of the IGBT stack, a drift region over the injector region opposite the first surface, a pair of junction implants in the IGBT stack along the second surface of the IGBT stack, and a field termination region between the pair of junction implants in the IGBT stack along the second surface of the IGBT stack. The field termination region reduces the electric field presented between the junction implants of the IGBT device, thereby allowing for a better balance between the ON-state resistance and the longevity of the IGBT device.

According to one embodiment, the IGBT stack of the IGBT device further includes a spreading region over the drift region opposite the injector region.

According to an additional embodiment, a method for manufacturing an IGBT device includes the steps of providing an IGBT stack including an injector region and a drift region over the injector region, where the injector region provides a first surface of the IGBT stack opposite the drift region, providing a pair of junction implants in the IGBT stack along a second surface of the IGBT stack opposite the first surface, providing a field termination region between the pair of junction implants in the IGBT stack along the second surface of the IGBT stack, providing a collector contact over the first surface of the IGBT stack, and providing a gate contact and an emitter contact on the second surface of the IGBT stack. Again, the field termination region reduces the electric field presented between the junction implants of the IGBT device, thereby allowing for a better balance between the ON-state resistance and the longevity of the IGBT device.

According to one embodiment, the IGBT stack of the IGBT device further includes a spreading region over the drift region opposite the injector region.

Those skilled in the art will appreciate the scope of the present disclosure and realize additional aspects thereof after reading the following detailed description of the preferred embodiments in association with the accompanying drawing figures.

### BRIEF DESCRIPTION OF THE DRAWING FIGURES

The accompanying drawing figures incorporated in and forming a part of this specification illustrate several aspects of the disclosure, and together with the description serve to explain the principles of the disclosure.

FIG. 1 shows a conventional insulated gate bipolar transistor (IGBT) device.

FIG. 2 shows an IGBT device including a field termination region according to one embodiment of the present disclosure.

FIG. 3 shows a flow-chart illustrating a method for manufacturing the IGBT device shown in FIG. 2 according to one embodiment of the present disclosure.

FIGS. 4A-4K illustrate the method for manufacturing the IGBT device described by the flow chart in FIG. 3.

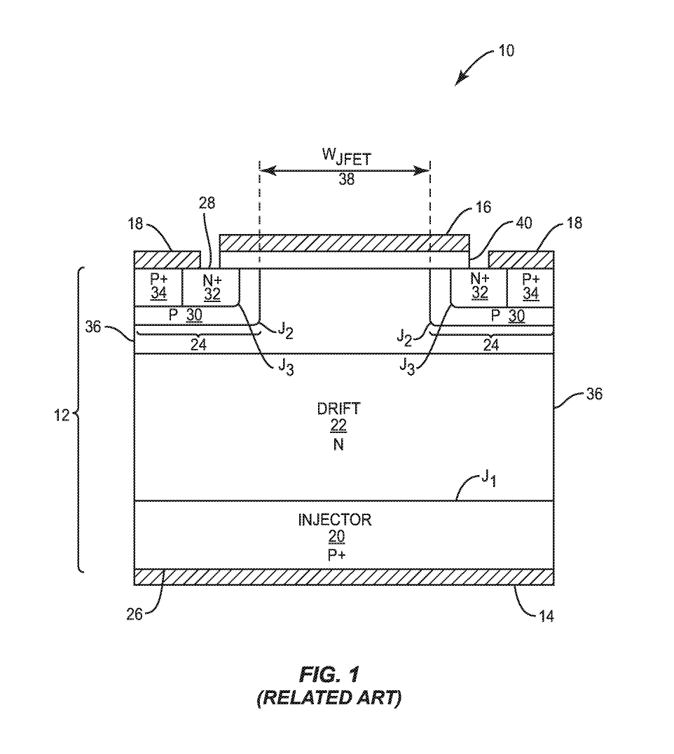

### DETAILED DESCRIPTION

The embodiments set forth below represent the necessary information to enable those skilled in the art to practice the embodiments and illustrate the best mode of practicing the embodiments. Upon reading the following description in light of the accompanying drawing figures, those skilled in the art will understand the concepts of the disclosure and will recognize applications of these concepts not particularly addressed herein. It should be understood that these concepts and applications fall within the scope of the disclosure and the accompanying claims.

It will be understood that, although the terms first, second, etc. may be used herein to describe various elements, these elements should not be limited by these terms. These terms are only used to distinguish one element from another. For example, a first element could be termed a second element, and, similarly, a second element could be termed a first element, without departing from the scope of the present disclosure. As used herein, the term “and/or” includes any and all combinations of one or more of the associated listed items.

It will be understood that when an element such as a layer, region, or substrate is referred to as being “on” or extending “onto” another element, it can be directly on or extend directly onto the other element or intervening elements may also be present. In contrast, when an element is referred to as being “directly on” or extending “directly onto” another element, there are no intervening elements present. Likewise, it will be understood that when an element such as a layer, region, or substrate is referred to as being “over” or extending “over” another element, it can be directly over or extend directly over the other element or intervening elements may also be present. In contrast, when an element is referred to as being “directly over” or extending “directly over” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

Relative terms such as “below” or “above” or “upper” or “lower” or “horizontal” or “vertical” may be used herein to describe a relationship of one element, layer, or region to another element, layer, or region as illustrated in the Figures. It will be understood that these terms and those discussed above are intended to encompass different orientations of the device in addition to the orientation depicted in the Figures.

The terminology used herein is for the purpose of describing particular embodiments only and is not intended to be limiting of the disclosure. As used herein, the singular forms “a,” “an,” and “the” are intended to include the plural forms as well, unless the context clearly indicates otherwise. It will be further understood that the terms “comprises,” “comprising,” “includes,” and/or “including” when used herein specify the presence of stated features, integers, steps, operations, elements, and/or components, but do not preclude the presence or addition of one or more other features, integers, steps, operations, elements, components, and/or groups thereof.

Unless otherwise defined, all terms (including technical and scientific terms) used herein have the same meaning as commonly understood by one of ordinary skill in the art to which this disclosure belongs. It will be further understood that terms used herein should be interpreted as having a meaning that is consistent with their meaning in the context of this specification and the relevant art and will not be interpreted in an idealized or overly formal sense unless expressly so defined herein.

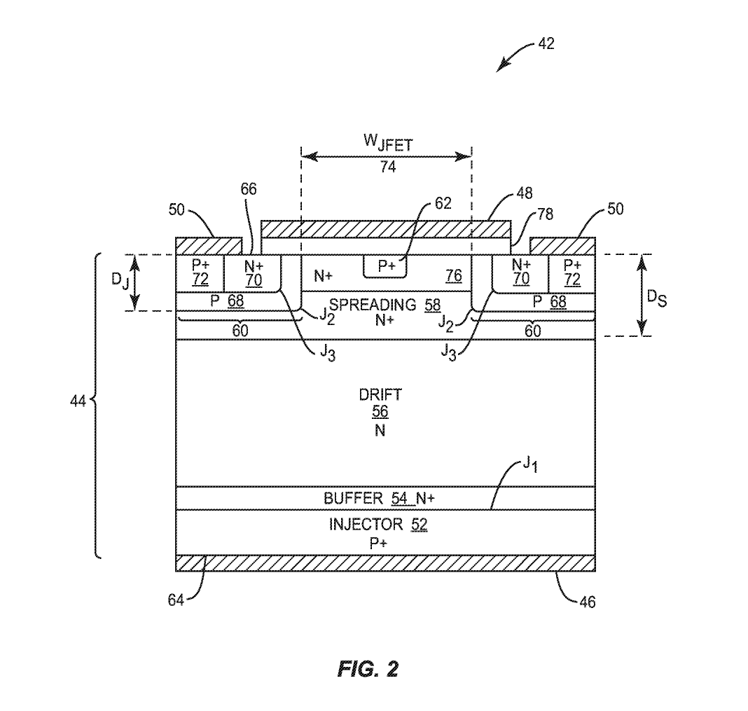

Turning now to FIG. 2, an IGBT device 42 is shown according to one embodiment of the present disclosure. The IGBT device 42 includes an IGBT stack 44, a collector contact 46, a gate contact 48, and an emitter contact 50. The IGBT stack 44 includes an injector region 52 adjacent to the collector contact 46, a buffer region 54 over the injector region 52 opposite the collector contact 46, a drift region 56 over the buffer region 54 opposite the injector region 52, a spreading region 58 over the drift region 56 opposite the buffer region 54, a pair of junction implants 60 in the spreading region 58 along a surface of the spreading layer 58 opposite the drift region 56, and a field termination region 62 between the junction implants 60 in the spreading region 58 along a surface of the spreading region 58 opposite the drift region 56. The injector region 52 provides a first surface 64 of the IGBT stack 44 on which the collector contact 46 is located, while the spreading region 58 provides a second surface 66 opposite the first surface 64 on which the gate contact 48 and the emitter contact 50 are located.

Each one of the junction implants 60 may be formed by an ion implantation process, and may include a base well 68, a source well 70, and an ohmic well 72. Each base well 68 is implanted in the IGBT stack 44 along the second surface 66 of the IGBT stack 44, and extends down towards the injector region 52 along a lateral edge of the IGBT stack 44 to a junction implant depth (D_{J}). The source well 70 may be formed in a shallow portion of the IGBT stack 44 along the second surface 66 of the IGBT stack 44, such that the source well 70 is surrounded by the base well 68. The ohmic well 72 may be formed next to the source well 70 in a shallow portion of the IGBT stack 44 along the second surface 66 of the IGBT stack 44. The spreading region 58 may extend down towards the injector region 52 to a spreading region depth (D_{S}), which is larger than the junction implant depth D_{J}, such that the spreading region 58 contains each one of the junction implants 60. According to one embodiment, the junction implant depth (D_{J}) is between about 0.5 μm to 1.5 μm, while the spreading region depth (D_{S}) is between about 1.5 μm to 10 μm. A junction field-effect transistor (JFET) gap 74 separates each one of the junction implants 60 in the IGBT device 42, and defines a JFET gap width W_{JFET} as the distance between each one of the junction implants 60. An additional JFET region 76 may be provided in the JFET gap 74, as discussed in further detail below.

The field termination region 62 may be provided in the center of the JFET gap 74 in the IGBT stack 44 along the second surface 66 of the IGBT stack 44. Providing the field termination region 62 between the junction implants 60 attenuates the electric field generated in the middle of the JFET gap 74 during operation of the IGBT device 42, thereby increasing the longevity of the IGBT device 42. Further, the field termination region 62 collects minority carriers during switching to improve the speed of the IGBT device 42. Finally, the field termination region 62 allows for a larger JFET gap width W_{JFET}, as the field termination region 62 allows the IGBT device 42 to accommodate larger electric fields without damage to the device. A larger JFET gap width W_{JFET} results in a desirable drop in the ON-state resistance of the IGBT device 42. Although only one field termination region 62 is shown in the IGBT device 42, any number of field termination regions 62 may be used in the JFET gap 74 arranged in any configuration without departing from the principles disclosed herein.

According to one embodiment, the field termination region 62 is a highly doped P region with a doping concentration between about 1E16 cm⁻³ and 1E20 cm⁻³. Further, the field termination region 62 may be about 1.0 μm wide and extend to a depth of about 0.3 μm. In different embodiments, the field termination region 62 may be contained by the JFET region 76, the spreading region 58, or both. As discussed above, the field termination region 62 may enable a larger JFET gap width W_{JFET} that would otherwise be possible in a conventional IGBT device due to the attenuation of the electric field presented between the junction implants 60. In one embodiment, the JFET gap width W_{JFET} is larger than 5 μm, and may extend up to 20 μm while maintaining desirable performance characteristics of the IGBT device 42.

A gate oxide layer 78 may be positioned on the second surface 66 of the IGBT stack 44 such that the gate oxide layer 78 extends laterally between a portion of the surface of each source well 70 in the junction implants 60. The gate contact 48 may be located over the gate oxide layer 78. The emitter contact 50 may be split into two portions, each of which is located on the second surface 66 of the IGBT stack 44 such that each portion partially overlaps both the base region 68 and the source region 70, without contacting the gate contact 48 or the gate oxide layer 78.

A first junction J₁ between the injector region 52 and the buffer region 54, a second junction J₂ between each base well 68 and the spreading region 58, and a third junction J₃ between each source well 70 and each base well 68 are controlled to operate in one of a forward-bias mode of operation or a reverse-bias mode of operation based on the biasing of the IGBT device 42. Accordingly, the flow of current between the collector contact 46 and the emitter contact 50 is controlled.

According to one embodiment, the injector region 52 is a highly doped P region with a doping concentration between 1E16 cm⁻³ to 1E21 cm⁻³. The buffer region 54 may be a highly doped N region with a doping concentration between 5E15 cm⁻³ to 1E17 cm⁻³. The drift region 56 may be a lightly doped N region with a doping concentration between 1E13 cm⁻³ to 1E15 cm⁻³. In some embodiments, the drift region 56 may include a notably light concentration of dopants, in order to improve one or more performance parameters of the IGBT device 42 as discussed in further detail below. The spreading region 58 may be a highly doped N region with a doping concentration between 5E15 cm⁻³ to 5E16 cm⁻³. Further, in some embodiments, the spreading region 58 may include a graduated doping concentration, such that as the spreading region 58 extends away from the second surface 66 of the IGBT stack 44, the doping concentration of the spreading region 58 gradually decreases. For example, the portion of the spreading region 58 directly adjacent to the first surface 66 of the IGBT stack 44 may be doped at a concentration of 5E16 cm⁻³, while the portion of the spreading region 58 directly adjacent to the drift region 56 may have a doping concentration of about 5E15 cm⁻³. The JFET region 76 may also be a highly doped N region with a doping concentration between 1E16 cm⁻³ to 1E18 cm⁻³. Further, the base well 68 may be a P doped region with a doping concentration between 5E17 cm⁻³ and 1E19 cm⁻³ and the source well 70 may be a highly doped N region with a doping concentration between 1E19 cm⁻³ and 1E21 cm⁻³.

The injector region 52 may be doped with aluminum, boron, or the like. Those of ordinary skill in the art will appreciate that many different dopants exist that may be suitable for doping the injector region 52, all of which are contemplated herein. The buffer region 54, the drift region 56, the spreading region 58, and the JFET region 76 may be doped with nitrogen, phosphorous, or the like. Those of ordinary skill in the art will appreciate that many different dopants exist that may be suitable for doping the buffer region 54, the drift region 56, the spreading region 58, and the JFET region 76, all of which are contemplated herein.

According to one embodiment, the injector region 52 is generated by an epitaxy process. According to an additional embodiment, the injector region 52 is formed by an ion implantation process. Those of ordinary skill in the art will appreciate that numerous different processes exist for generating the injector region 52, all of which are contemplated herein. The spreading region 58 and the JFET region 76 may similarly be formed by either an epitaxy process or an ion implantation process. Those of ordinary skill in the art will appreciate that numerous different processes exist for generating the spreading region 58 and the JFET region 76, all of which are contemplated herein.

According to one embodiment, the IGBT stack 44 is a wide band-gap semiconductor material. For example, the IGBT stack 44 may be Silicon Carbide (SiC). As discussed above, manufacturing limitations inherent in SiC technologies will generally result in diminished carrier lifetimes and/or carrier concentrations in the injector region 52 of a SiC IGBT device. As a result, SiC IGBT devices generally suffer from a reduced amount of “backside injection,” which results in poor conductivity modulation and an increased ON-state resistance of the SiC IGBT device. Further, damaged regions below each one of the junction implants of a SiC IGBT device result in significantly degraded carrier lifetimes at or near these damaged regions. These so-called “end-of-range” defects effectively prevent the modulation of current in the upper portion of the drift region in a SiC IGBT device, which in turn significantly increases the resistance in this area. As a result of the increased resistance in the upper portion of the drift region, current flow in the SiC IGBT device may be significantly reduced, or cut off altogether. The spreading region 58 of the IGBT device 42 is therefore provided to enhance the conductivity modulation in the upper portion of the IGBT device 42. Those of ordinary skill in the art will recognize that the spreading region 58, together with a larger JFET gap width W_{JFET} made possible by the field termination region 62 allow for a significant reduction in the ON-state resistance of the IGBT device 42, thereby improving the performance thereof.

As will be appreciated by those of ordinary skill in the art, the IGBT device 42 shown in FIG. 2 is an N-type IGBT. Those of ordinary skill in the art will further appreciate that the principles of the present disclosure may be applied to P-type IGBT devices by switching the doping types of each of the regions described herein.

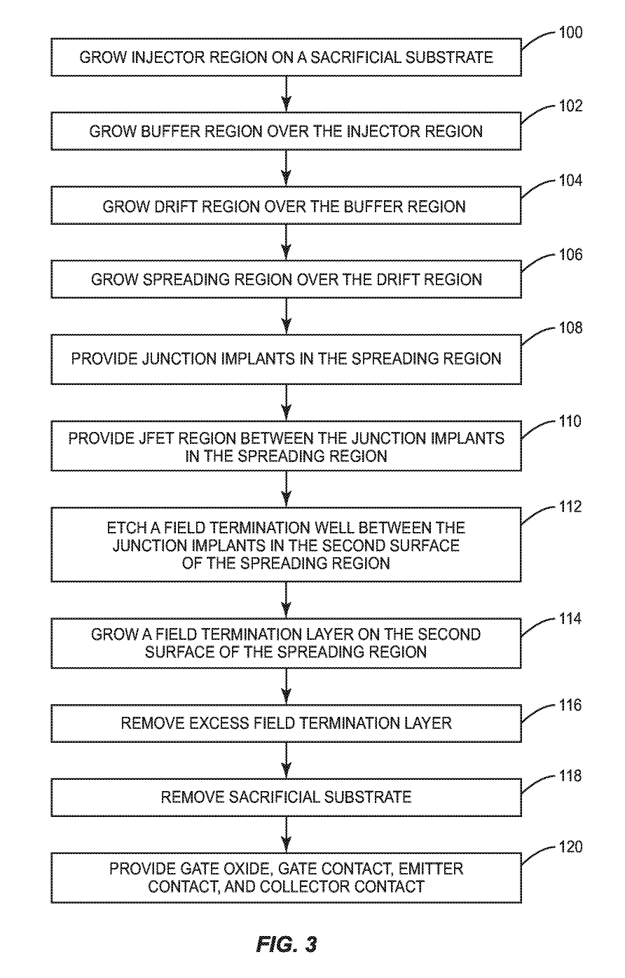

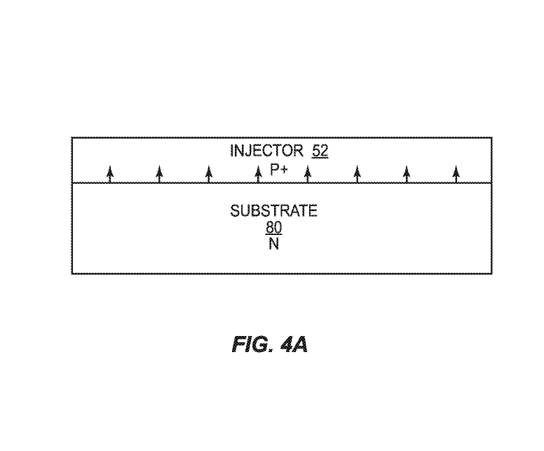

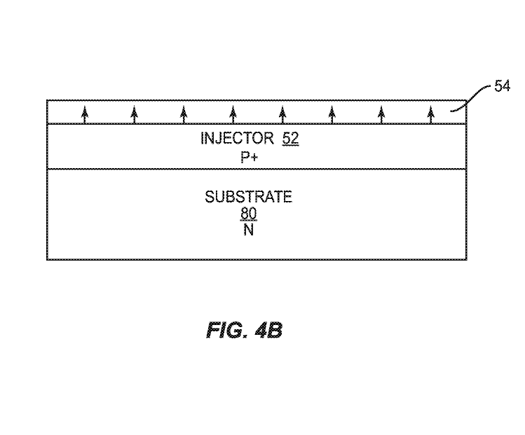

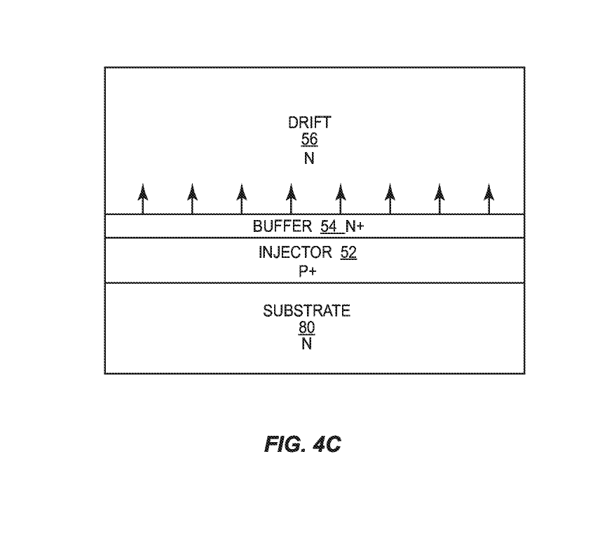

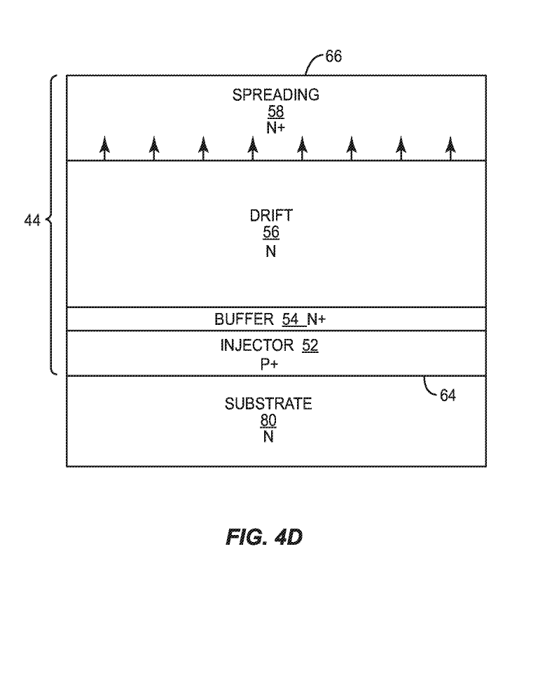

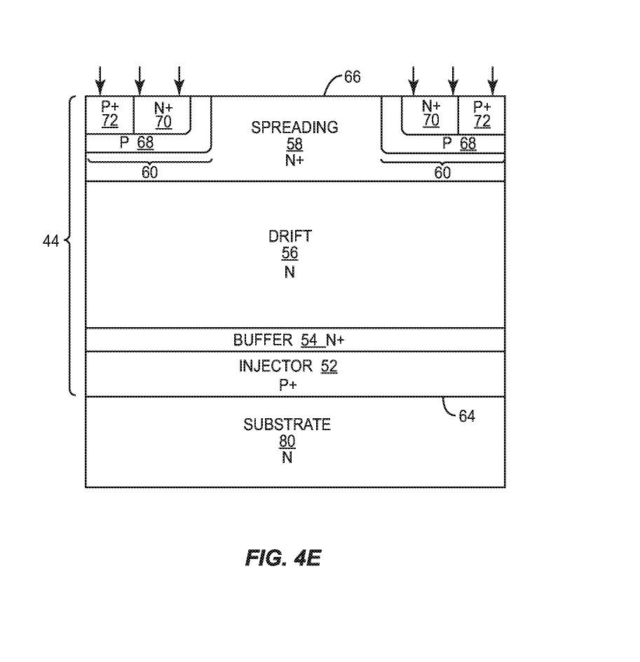

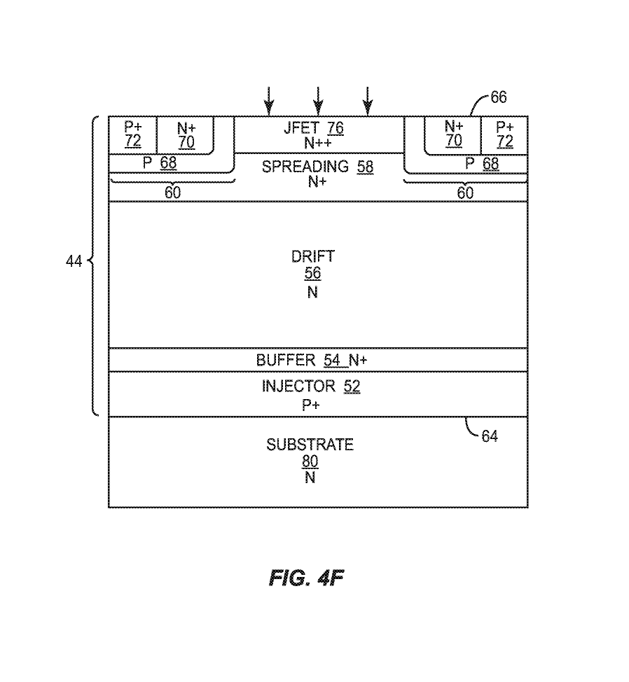

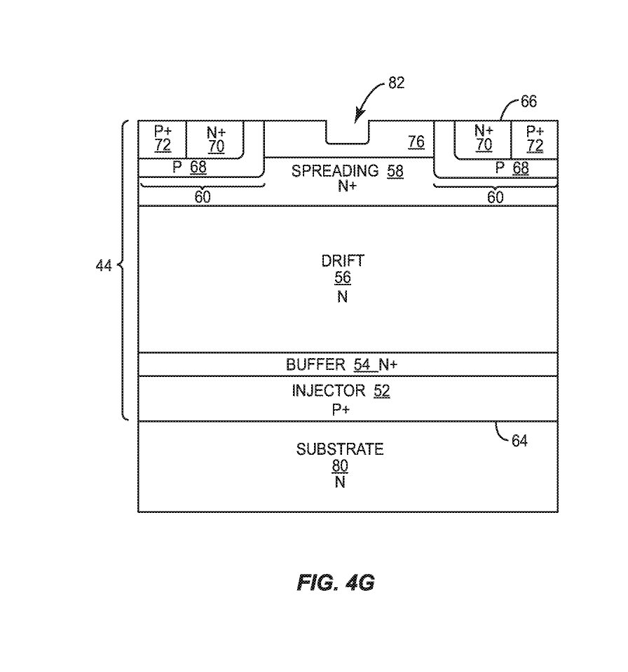

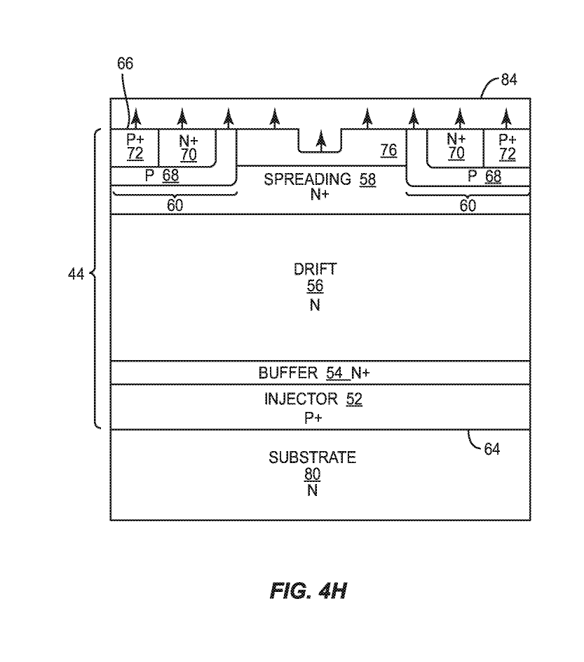

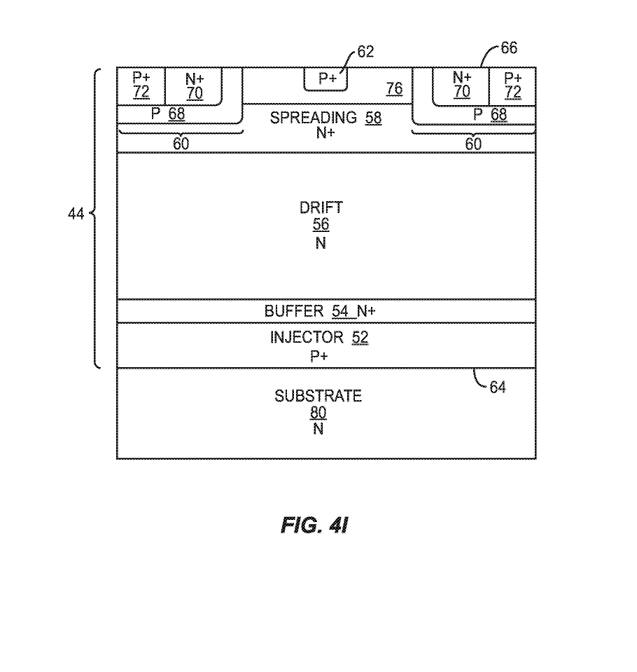

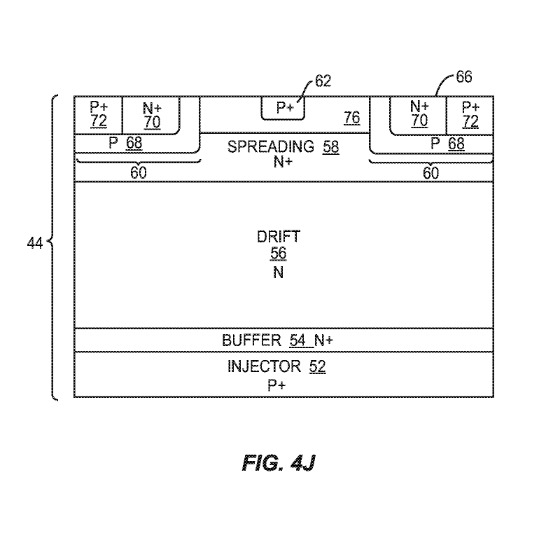

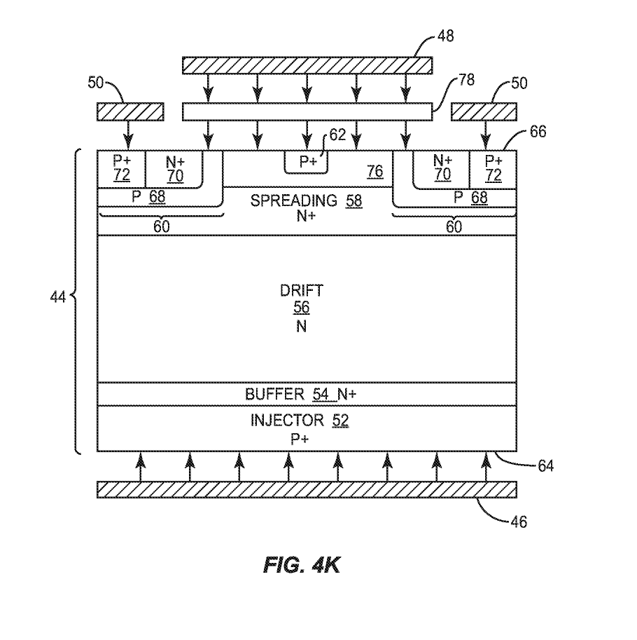

FIGS. 3 and 4A-4K illustrate a process for manufacturing the IGBT device 42 shown in FIG. 2 according to one embodiment of the present disclosure. First, the injector region 52 is grown on a sacrificial substrate 80 (step 100 and FIG. 4A). As will be appreciated by those of ordinary skill in the art, the sacrificial substrate 80 may be required due to the unavailability of pre-manufactured P-type substrates in SiC. Those of ordinary skill in the art will further appreciate that the sacrificial substrate 80 may be omitted in some circumstances, for example, if the IGBT device 42 being manufactured is a P-type IGBT device 42 with an N-type injector region 52, in which case the injector region 52 may be used as the substrate for growing the additional regions of the device. The buffer region 54 is then grown over the injector region 52 (step 102 and FIG. 4B), and the drift region 56 is grown over the buffer region 54 (step 104 and FIG. 4C). Next, the spreading region 58 is grown over the drift region 56 (step 106 and FIG. 4D) to complete the IGBT stack 44. The injector region 52, the buffer region 54, the drift region 56, and the spreading region 58 may be grown, for example, by a Chemical Vapor Deposition (CVD) process, however, those of ordinary skill in the art will appreciate that a number of different processes exist for growing the injector region 52, the buffer region 54, the drift region 56, and the spreading region 58, all of which are contemplated herein.

The junction implants 60 are then provided in the IGBT stack 44 along the second surface 66 of the IGBT stack 44 (step 108 and FIG. 4E). The junction implants 60 may be provided, for example, by one or more ion implantation processes, however, those of ordinary skill in the art will appreciate that a number of different processes exist for providing the junction implants, all of which are contemplated herein. Next, the JFET region 76 is provided between each one of the junction implants 60 in the IGBT stack 44 along the second surface 66 of the IGBT stack 44 (step 110 and FIG. 4F). The JFET region 76 may be provided, for example, by an ion implantation process. In other embodiments, the JFET region 76 may be provided via an epitaxial growth process that takes place before providing the junction implants 60. Further, providing the JFET region 76 may also involve activating the JFET region 76 and the junction implants 60, for example, by rapid thermal processing. Those of ordinary skill in the art will appreciate that a number of different processes exist for providing the JFET region 76, all of which are contemplated herein. A field termination well 82 is then etched into the second surface 66 of the IGBT stack 44 between the junction implants 60 (step 112 and FIG. 4G). The field termination well 82 may be provided via a photo-resistive etching process, in which a photo-resistive mask is provided on the second surface of the IGBT stack 44, the field termination well 82 is etched via a chemical etching process, and the photo-resistive mask is removed. In other embodiments, the field termination well 82 may be provided by a mechanical etching process. Those of ordinary skill in the art will appreciate that a number of different processes for providing the field termination well 82 exist, all of which are contemplated herein.

Next, a field termination layer 84 is grown on the second surface 66 of the IGBT stack 44 and in the field termination well 82 (step 114 and FIG. 4H), and the excess portions of the field termination layer 84 are removed to re-expose the second surface 66 of the IGBT stack 44, leaving the field termination region 62 in the field termination well 82 (step 116 and FIG. 4I). The field termination layer 84 may be grown by any suitable process, as will be appreciated by those of ordinary skill in the art. Further, the excess portions of the field termination layer 84 may be removed by any suitable etching or grinding process. By first etching the field termination well 82, then filling it via an epitaxial growth process, defects that may otherwise be caused if the field termination region 62 were formed via an ion implantation process may be avoided, thereby maintaining the integrity of the IGBT stack 44 and increasing the performance of the IGBT device 42. However, depending on the required performance of the IGBT device and other design considerations, the field termination region 62 may also be formed via an ion implantation process according to one or more embodiments. The sacrificial substrate 80 is then removed (step 118 and FIG. 4J). The sacrificial substrate 80 may be removed, for example, by a grinding process, however, those of ordinary skill in the art will appreciate that a number of different processes for removing the sacrificial substrate 80 exist, all of which are contemplated herein. Finally, the gate oxide layer 78, the gate contact 48, and the emitter contact 50 are provided on the second surface 66 of the IGBT stack 44, while the collector contact 46 is provided on the first surface 64 of the IGBT stack 58 (step 120 and FIG. 4K). Those of ordinary skill in the art will appreciate that any number of oxidation and/or metallization processes exist for providing the gate oxide layer 78, the gate contact 48, the emitter contact 50, and the collector contact 46, all of which are contemplated herein.

Those skilled in the art will recognize improvements and modifications to the preferred embodiments of the present disclosure. All such improvements and modifications are considered within the scope of the concepts disclosed herein and the claims that follow.

1. An insulated gate bipolar transistor (IGBT) device comprising:
an IGBT stack comprising:
an injector region, the injector region providing a first surface of the IGBT stack;
a drift region over the injector region opposite the first surface;
a pair of junction implants in the IGBT stack along a second surface of the IGBT stack, which is opposite the first surface;
a junction field effect transistor (JFET) region between the pair of junction implants along the second surface of the IGBT stack, wherein a doping concentration of the JFET region is different from a doping concentration of the drift region; and
a field termination region between the pair of junction implants and in the JFET region;
a collector contact over the first surface; and
a gate contact and an emitter contact on the second surface.

2. The IGBT device of claim 1 wherein the pair of junction implants are laterally separated from one another along the second surface by a distance greater than 5 μm.

3. The IGBT device of claim 2 wherein the pair of junction implants are laterally separated from one another along the second surface by a distance less than 20 μm.

4. The IGBT device of claim 1 wherein the pair of junction implants are contained by the drift region.

5. The IGBT device of claim 1 wherein:
the injector region is a heavily doped P region;
the drift region is a lightly doped N region;
the JFET region is a heavily doped N region; and
the field termination region is a heavily doped P region.

6. The IGBT device of claim 5 wherein:
the injector region has a doping concentration in the range of about 5×10¹⁷ cm⁻³ to about 1×10²¹ cm⁻³;
the drift region has a doping concentration in the range of about 1×10¹³ cm⁻³ to about 1×10¹⁵ cm⁻³;
the JFET region has a doping concentration in the range of about 1×10¹⁶ cm⁻³ to about 1×10¹⁸ cm⁻³; and
the field termination region has a doping concentration in the range of about 1×10¹⁶ cm⁻³ to about 1×10²⁰ cm⁻³.

7. The IGBT device of claim 1 wherein each one of the pair of junction implants comprises:
a base well; and
a source well within the base well.

8. The IGBT device of claim 7 wherein:
the base well is a heavily doped P region; and
the source well is an N region.

9. The IGBT device of claim 7 wherein:
the gate contact runs between each source well in the pair of junction implants on the second surface; and
the emitter contact partially overlaps the source well and the base well in each one of the pair of junction implants, respectively, without contacting the gate contact.

10. The IGBT device of claim 9 further comprising a gate oxide layer between the gate contact and the second surface.

11. The IGBT device of claim 1 wherein the IGBT stack further comprises a buffer region between the injector region and the drift region.

12. The IGBT device of claim 1 further comprising a junction field-effect transistor (JFET) region between each one of the junction implants in the IGBT stack along the second surface, such that the field termination region is contained within the JFET region.

13. The IGBT device of claim 1 wherein the IGBT stack is a wide band-gap semiconductor material.

14. The IGBT device of claim 13 wherein the IGBT stack is Silicon Carbide (SiC).

15. The IGBT device of claim 1 wherein the IGBT stack further comprises a spreading region over the drift region opposite the injector region.

16. The IGBT device of claim 15 wherein the pair of junction implants are laterally separated from one another along the second surface by a distance greater than 5 μm.

17. The IGBT device of claim 16 wherein the pair of junction implants are laterally separated from one another along the second surface by a distance less than 20 μm.

18. The IGBT device of claim 15 wherein the pair of junction implants are contained by the spreading region.

19. The IGBT device of claim 15 wherein:
the injector region is a heavily doped P region;
the drift region is a lightly doped N region;
the spreading region is a heavily doped N region; and
the field termination region is a heavily doped P region.

20. The IGBT device of claim 19 wherein:
the injector region has a doping concentration in the range of about 5×10¹⁷ cm⁻³ to about 1×10²¹ cm⁻³;
the drift region has a doping concentration in the range of about 1×10⁻³ cm to about 1×10¹⁵ cm⁻³;
the spreading region has a doping concentration in the range of about 1×10¹⁶ cm⁻³ to about 5×10¹⁶ cm⁻³; and
the field termination region has a doping concentration in the range of about 1×10¹⁶ cm⁻³ to about 1×10²⁰ cm⁻³.

21. The IGBT device of claim 15 wherein each one of the pair of junction implants comprises:
a base well; and
a source well within the base well.

22. The IGBT device of claim 15 wherein the IGBT stack further comprises a buffer region between the injector region and the drift region.

23. The IGBT device of claim 15 wherein the IGBT stack is a wide band-gap semiconductor material.

24. The IGBT device of claim 23 wherein the IGBT stack is Silicon Carbide (SiC).

25. A method of manufacturing an insulated gate bipolar transistor (IGBT) device comprising:
providing an IGBT stack including an injector region and a drift region over the injector region, the injector region providing a first surface of the IGBT stack opposite the drift region;
providing a pair of junction implants in the IGBT stack along a second surface of the IGBT stack, which is opposite the first surface;
providing a junction field effect transistor (JFET) region in the IGBT stack between the pair of junction implants along the second surface of the IGBT stack;
providing a field termination region between the pair of junction implants in the JFET region;
providing a collector contact over the first surface; and
providing a gate contact and an emitter contact on the second surface.

26. The method of claim 25 wherein the pair of junction implants are laterally separated from one another along the second surface by a distance greater than 5 μm.

27. The method of claim 26 wherein the pair of junction implants are laterally separated from one another along the second surface by a distance less than 20 μm.

28. The method of claim 25 wherein the pair of junction implants are contained by the drift region.

29. The method of claim 25 wherein:
the injector region is a heavily doped P region;
the drift region is a lightly doped N region;
the JFET region is a heavily doped N region; and
the field termination region is a heavily doped P region.

30. The method of claim 29 wherein:
the injector region has a doping concentration in the range of about 1×10¹⁷ cm⁻³ to about 1×10²¹ cm⁻³;
the drift region has a doping concentration in the range of about 1×10¹³ cm⁻³ to about 1×10¹⁵ cm⁻³;
the JFET region has a doping concentration in the range of about 1×10¹⁶ cm⁻³ to about 1×10¹⁸ cm⁻³; and
the field termination region has a doping concentration in the range of about 1×10¹⁶ cm⁻³ to about 1×10²⁰ cm⁻³.
